(19) United States
(12) Patent Application Publication
(10) Pub. No.: US 2014/0308801 A1
(43) Pub. Date: Oct. 16, 2014

(54) Anything on Glass

(71) Applicant: The Board of Trustees of the Leland Stanford Junior University, Palo Alto, CA (US)

(72) Inventors: Jae Hyung Lee, Palo Alto, CA (US); Woo Shik Jung, Sunnyvale, CA (US); Krishna C. Saraswat, Saratoga, CA (US)

(73) Assignee: The Board of Trustees of the Leland Stanford Junior University, Palo Alto, CA (US)

(21) Appl. No.: 14/251,164

(22) Filed: Apr. 11, 2014

Related U.S. Application Data
(60) Provisional application No. 61/811,657, filed on Apr. 12, 2013.

(51) Int. Cl. H01L 21/18

(52) U.S. Cl. CPC H01L 21/187
USPC 438/459

(57) ABSTRACT

Bonding of one or more semiconductor layers to a glass substrate is facilitated by depositing spin-on-glass (SOG) on the top of the semiconductor layers. The SOG is then bonded to the glass substrate, and after that, the original substrate of the semiconductor layers is removed. The resulting structure has the semiconductor layers disposed on the glass substrate with a layer of SOG sandwiched between. Bonding is always between glass and glass, and is independent of the composition of the target layers. Thus, it can provide “anything on glass”. For example, X-on-insulator (XOI), where X can be silicon, germanium, GaAs, GaN, SiC, graphene, etc. The spin-on-glass also helps with the surface roughness requirement.

### CROSS REFERENCE TO RELATED APPLICATIONS

This application claims the benefit of U.S. provisional patent application 61/811,657, filed on Apr. 12, 2013, and hereby incorporated by reference in its entirety.

### GOVERNMENT SPONSORSHIP

This invention was made with Government support under contract number N66001-10-1-4004 awarded by the Defense Advanced Research Projects Agency. The Government has certain rights in this invention.

### FIELD OF THE INVENTION

This invention relates to transferring semiconductor structures to a glass substrate.

### BACKGROUND

It is often desirable to transfer a semiconductor layer to a glass substrate. Conventional approaches for performing this operation include direct bonding and anodic bonding. Direct bonding requires extremely smooth surfaces (e.g., <0.2 nm surface roughness RMS (root mean square)). Heat (e.g., 400-600° C.) and pressure (e.g., 2000-3000 N) are applied to bond the semiconductor layer to the glass substrate. Direct bonding is based on forming covalent bonds between the glass substrate and the semiconductor layer. Direct bonding tends to be a difficult process with low yield. For example, chemical-mechanical polishing (CMP), which is often required to obtain the required smooth surfaces, tends to be an expensive and time consuming process. Furthermore, CMP requires a material-specific slurry, so if a need arises to bond a new material to a glass substrate, it may take a significant amount of time to develop a suitable CMP process for smoothing surfaces of the new material.

Anodic bonding is another conventional approach for transferring a semiconductor layer to a glass substrate. For anodic bonding, the surface roughness does not need to be as low as for direct bonding (e.g., <10 nm RMS surface roughness will usually be sufficient). Heat (e.g., 300-400° C.), pressure (e.g., 200-500 N) and high voltage are applied to bond the semiconductor layer to the glass substrate. However, the high applied voltage of conventional anodic bonding can damage the semiconductor layer. Sodium contamination of the semiconductor layer from contact with the glass substrate can also be a problem.

Since both conventional direct bonding and anodic bonding have significant disadvantages when transferring semiconductor layers to glass substrates, it would be an advance in the art to provide improved transfer of semiconductors to glass substrates.

### SUMMARY

In this work, bonding of one or more target layers to a glass substrate is facilitated by depositing spin-on-glass (SOG) on the top of the target layers. The spin-on-glass is then bonded to the glass substrate, and after that, the original substrate of the target layers is removed. The resulting structure has the target layers disposed on the glass substrate with a layer of SOG sandwiched in between.

The main advantage provided by the present approach is that bonding is always between glass and glass, and is independent of the composition of the target layers. Thus, it can provide “anything on glass”. For example, X-on-insulator (XOI), where X can be silicon, germanium, GaAs, GaN, SiC, graphene, etc. The spin-on-glass helps with the surface roughness requirement. For example, semiconductor layers as-grown can be too rough for either anodic bonding or direct bonding. Deposition of SOG usually results in a surface that is smooth enough for anodic bonding without further polishing. As described in more detail below, anodic bonding can be performed on target layers coated with SOG in such a way as to avoid the problems of damaging the target layers by high voltage and/or sodium diffusion.

If direct bonding is employed after deposition of the SOG, then further polishing will usually be needed. However, this polishing process is independent of the composition of the target layers, and CMP of glass is a well-characterized process. Thus, direct bonding after deposition of SOG (a single direct bonding process) is much easier than conventional direct bonding (different bonding processes for each target layer composition).

The present approach can be combined with other layer transfer techniques, such as the Smart-Cut® approach described in U.S. Pat. No. 5,882,987, or porous silicon layer transfer for robust and cost effective processing. Transparent glass substrates can enable optical applications such as solar cells or light emitting diodes (LEDs). The present approach may facilitate manufacturing of three-dimensional integrated circuits by providing a reliable vertical bonding process.

Applications include, but are not limited to: micro electromechanical systems (MEMS) devices, electronic devices (e.g., high-end CMOS devices, high-power/high-temperature electronic devices), optical devices (e.g., CCD cameras, LEDs, lasers, waveguides, photovoltaic cells), and 3D ICs (3D stacked DRAMs, 3D logic SOC applications). Strain-induced bandgap engineering can be used in connection with layers transferred to glass substrates in this manner.

### BRIEF DESCRIPTION OF THE DRAWINGS

FIGS. 1A-E show a first exemplary method for transfer to a glass substrate.

FIGS. 2A-E show a second exemplary method for transfer to a glass substrate.

FIGS. 3A-F show a third exemplary method for transfer to a glass substrate.

FIG. 4 shows measured Raman spectra for a strained germanium layer transferred to a glass substrate that was plastically deformed.

FIG. 5 shows measured Raman spectra for strained germanium layers that were transferred to a glass substrate, where the spin-on glass was annealed.

FIG. 6 shows strain in the germanium layers calculated from the results of FIG. 5.

### DETAILED DESCRIPTION

An exemplary method of transfer to a glass substrate includes the following steps:

1) Providing a first substrate, where one or more target layers are disposed on the first substrate. Typically, the target layers are grown on the first substrate, although this is not required.

2) Depositing spin-on-glass on the top surface of the target layers.

3) Bonding the spin-on-glass to a glass substrate. Any kind of bonding process can be employed for this step, including but not limited to anodic bonding and direct bonding.

4) Removing the first substrate after bonding the spin-on glass to the glass substrate.

It is convenient to define a glass substrate as any substrate having a glass top surface that is available for bonding. Thus, a substrate that is entirely glass is a “glass substrate” as defined above. Another example of a “glass substrate” as defined herein is a silicon wafer with an oxidized top surface. Such a wafer has a top layer of silicon oxide (i.e., glass), and therefore has the defining feature of a glass top surface that is available for bonding.

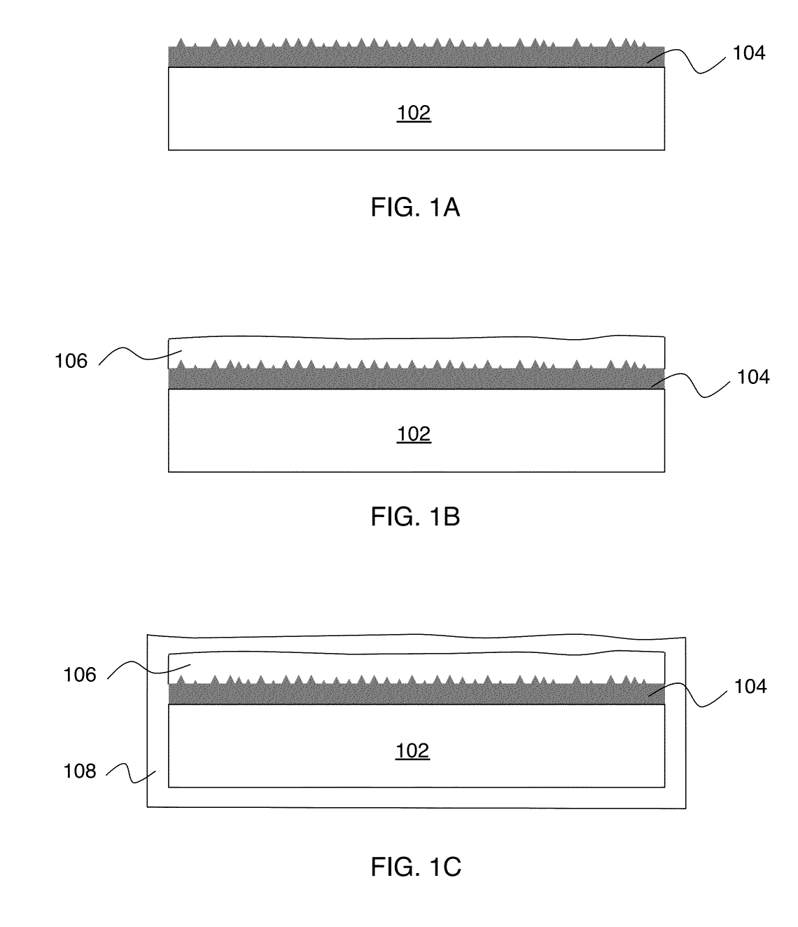

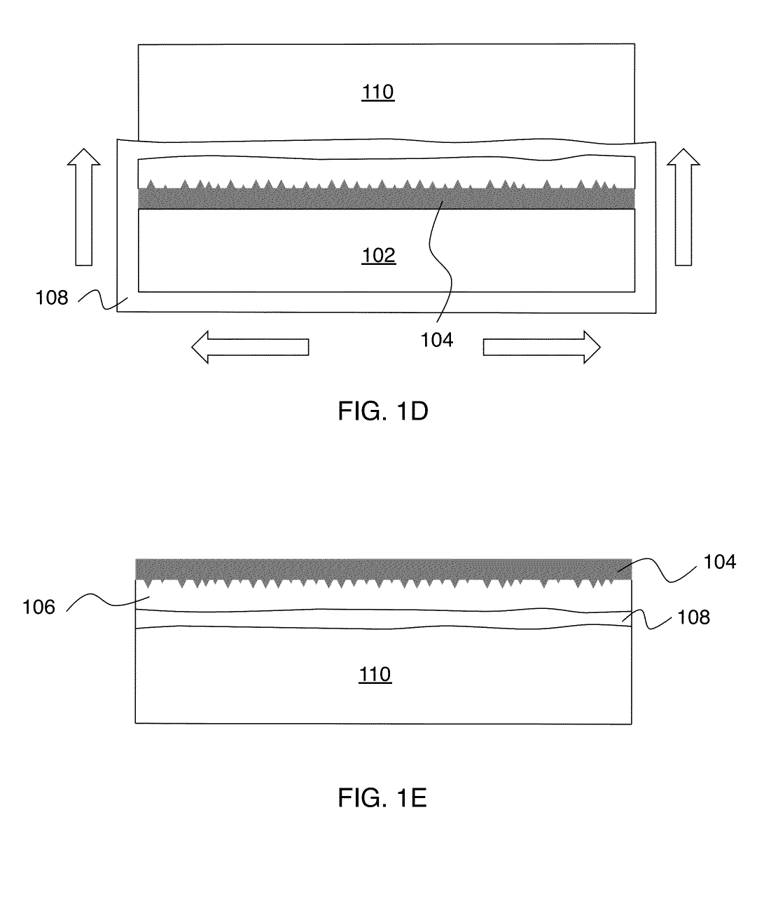

FIGS. 1A-E show a first exemplary method for transfer to a glass substrate. This example relates to anodic bonding and transfer of a Ge layer to a glass substrate. The specific materials of the examples herein are given for illustrative purposes. Practice of the invention does not depend critically on the composition of the target layers. Practice of the invention also does not depend critically on the composition of the first substrate.

In this example, first substrate 102 is silicon. Target layer 104 is germanium grown on silicon 102. FIG. 1A shows the resulting structure. Preferably, an SiGe layer is grown initially, followed by a Ge layer to minimize interface defects. Since the composition and structure of target layer(s) 104 is not critical, the SiGe layer is not shown for simplicity. Another variation is deposition of high-k materials (e.g., Al₂O₃, HfO₂) on top of the Ge to improve the interface quality of the target layers after transfer. As schematically shown on FIG. 1A, the top surface of layer 104 tends to be rough, and usually this surface roughness is too large for either anodic bonding or direct bonding.

FIG. 1B shows the result of depositing spin-on-glass 106 on the structure of FIG. 1A. Spin-on-glass is any glass that can be deposited onto a semiconductor wafer by a spinning process (analogous to deposition of a layer of photo-resist on a wafer by spinning the wafer). As schematically shown on FIG. 1B, this tends to provide a significant degree of surface smoothing (e.g., typical surface roughness here is <5 nm RMS). An important feature of this SOG deposition is that the spin-on-glass makes a good interface contact with target layer 104, despite the surface roughness that may be present at this interface. A variation here is deposition of low temperature oxide (LTO) prior to deposition of the spin-on-glass. This can be done to increase the total oxide layer thickness.

FIG. 1C shows the result of covering the entire structure of FIG. 1B with a layer of poly-silicon 108. The thickness of the poly-silicon layer can be about 100 nm. Other values for this thickness can also be employed, since this thickness is not critical. This poly-silicon is doped so as to be electrically conductive. Any approach can be employed for depositing this poly-silicon, such as low pressure chemical vapor deposition. More generally, any electrically conductive material can be employed as layer 108.

FIG. 1D shows the result of anodically bonding glass substrate 110 to the structure of FIG. 1C. The broad arrows show the current path. Since layer 108 is conductive, most of the voltage applied for anodic bonding drops across the interface between poly-silicon 108 and the glass substrate 110. In particular, target layer 104 is not subject to high voltage or high electric fields during the anodic bonding, and is also not subject to sodium contamination from glass substrate 110. The general idea here is to deposit an electrically conductive layer on top of the spin-on glass and then to anodically bond the electrically conductive layer to the glass substrate. This conductive layer serves to shield the target layers from applied electrical fields and from contamination during the anodic bonding. For anodic bonding, glass substrate 110 is preferably Pyrex®.

FIG. 1E shows the result of removing first substrate 102 (the view is flipped about a horizontal axis in going from FIG. 1D to FIG. 1E). For this example, a KOH etch can be used to remove the silicon substrate 102. The result of this process is transfer of target layer 104 from first substrate 102 to glass substrate 110. In early experiments, 100% yield was seen for two transfers.

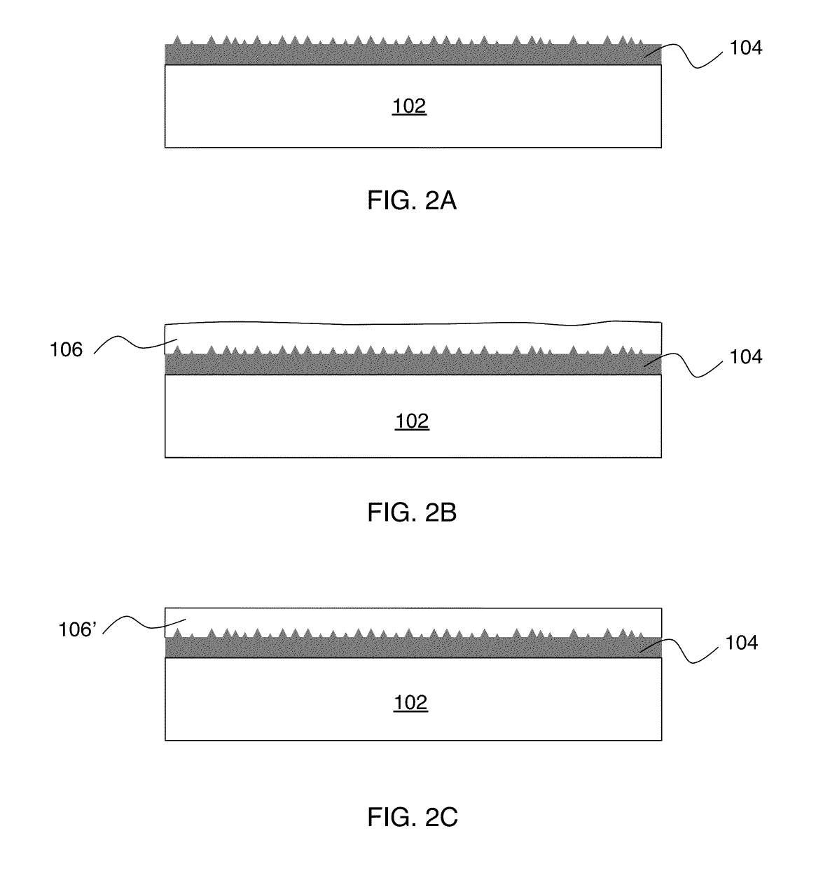

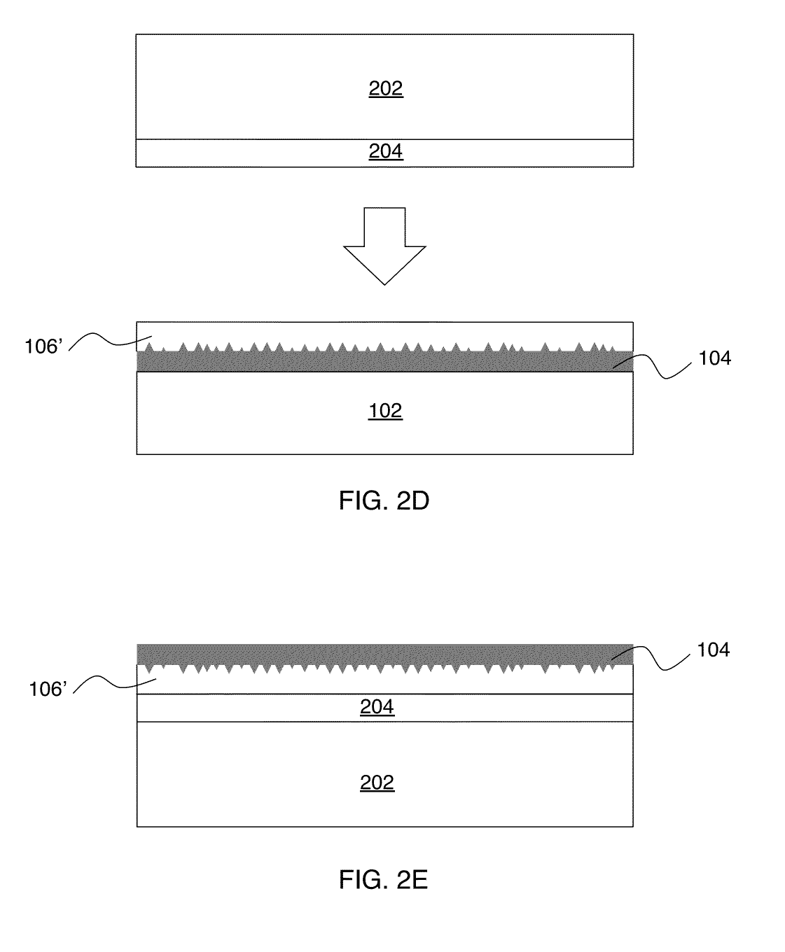

FIGS. 2A-E show a second exemplary method for transfer to a glass substrate. This example relates to direct bonding and transfer of a Ge layer to a glass substrate.

In this example, first substrate 102 is silicon. Target layer 104 is germanium grown on silicon 102. FIG. 2A shows the resulting structure, which is the same as the structure of FIG. 1A. FIG. 2B shows the result of depositing spin-on-glass 106 on the structure of FIG. 2A. The structure of FIG. 2B is the same as the structure of FIG. 1B. As indicated above, the surface roughness after this step is typically <5 nm RMS, which is too rough for direct bonding.

FIG. 2C shows the result of polishing SOG 106 to provide a smoothed SOG layer 106′. Chemical mechanical polishing can be used for this step. A surface roughness of <0.2 nm RMS can be achieved in this step. Since the only material that is being polished is SOG 106, this polishing step is independent of the composition of target layer 104. Polishing SOG is a well defined process in the industry, and can readily be performed according to known techniques.

FIG. 2D shows direct bonding of the structure of FIG. 2C to a glass substrate including a silicon substrate 202 and a silicon oxide layer 204. A strong bond can readily be achieved in this situation.

FIG. 2E shows the result of removing first substrate 102 from the bonded structure of FIG. 2D (the view is flipped about a horizontal axis in going from FIG. 2D to FIG. 2E). This step can be performed by etching substrate 102 in TMAH (tetramethylammonium hydroxide). The process of this example provides clean grade germanium on an oxide-silicon substrate, which can be useful for various applications in electronic device fabrication. Furthermore, a complicated CMP process is avoided. CMP is only needed to make the SOG surface smooth enough for direct bonding.

An important capability provided by the present approach is the ability to provide a planarized substrate that includes two or more distinct materials on a glass substrate. Normally, an XOI substrate for IC fabrication only has a single material (i.e., “X”) on top of the glass, so providing such multi-material substrates can significantly improve integrated circuit fabrication in cases where two or more different materials are needed.

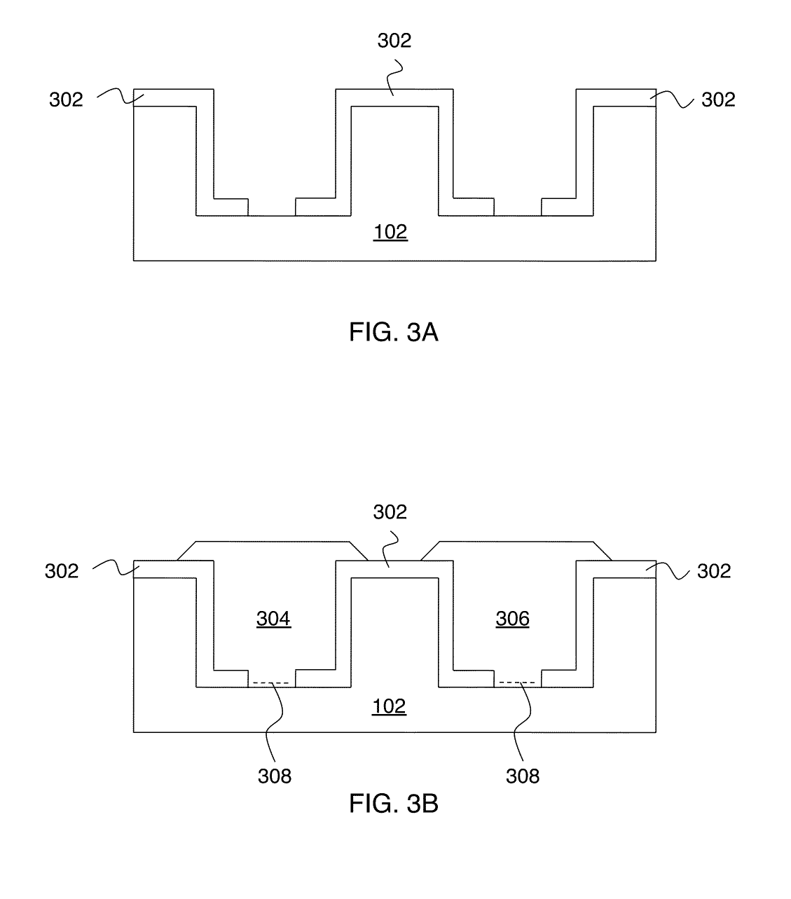

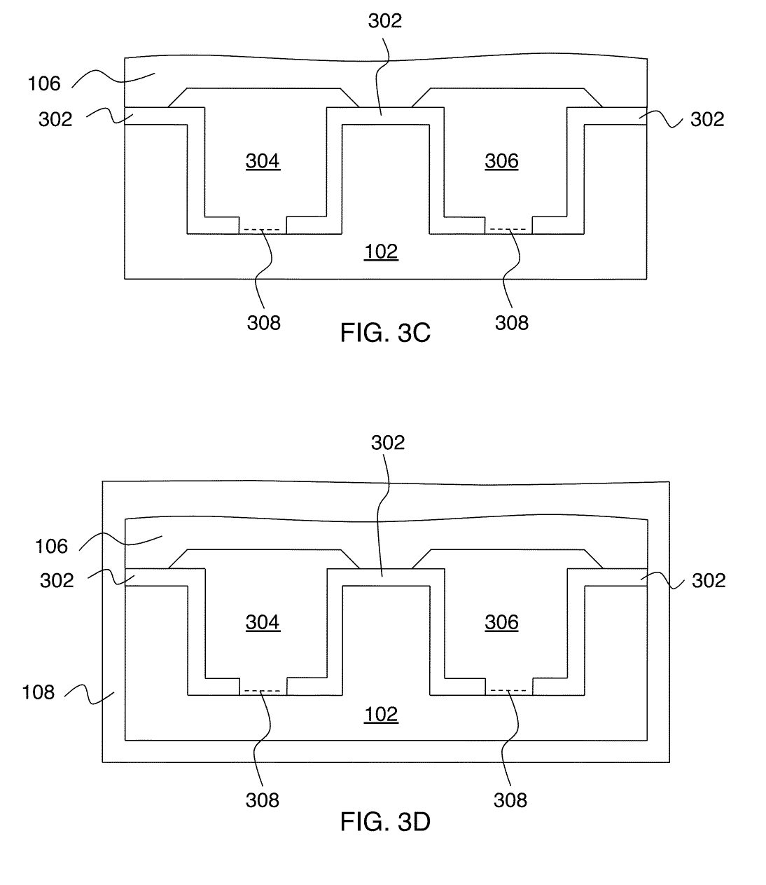

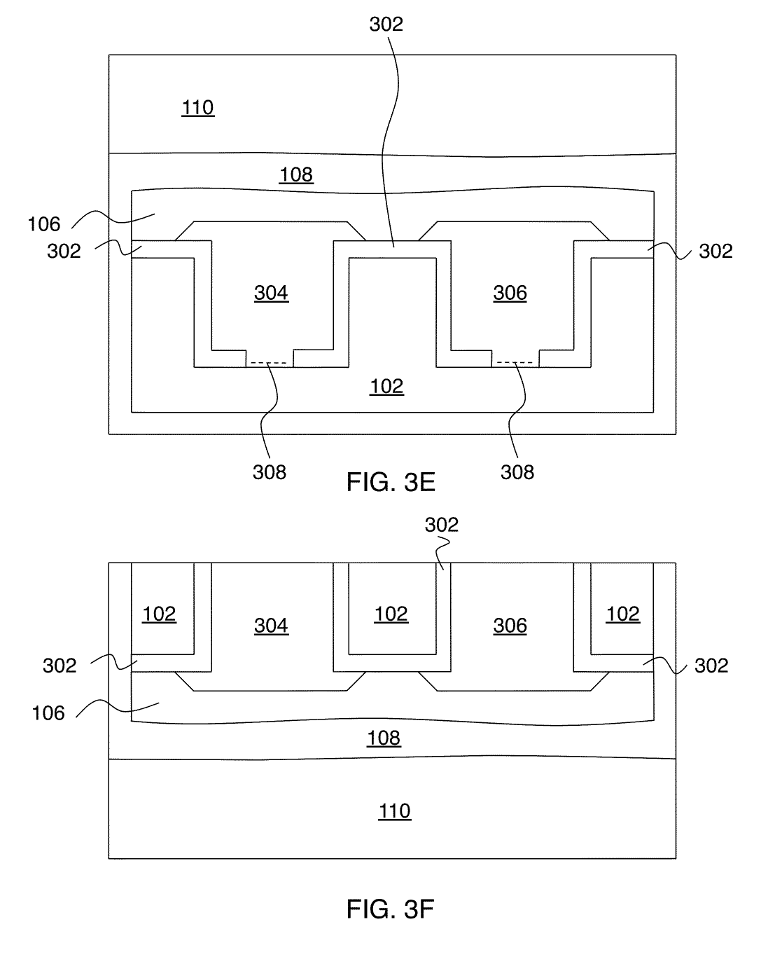

FIGS. 3A-F show an example of this approach. Here FIG. 3A shows a silicon substrate 102 having trenches fabricated in it (e.g., by dry etching). Oxide 302 is formed on the surface of substrate 102, and then the oxide is opened up at the bottom of the trenches. FIG. 3A shows the resulting structure.

FIG. 3B shows the result of filling in the trenches by epitaxial growth of different materials in the trenches. In this example, material 304 is germanium, and material 306 is a Si—Ge alloy. Control of which materials go into which trenches can be accomplished in various ways. One approach is to: 1) open up the Ge trenches, 2) grow the Ge in the Ge trenches, 3) open up the SiGe trenches, and 4) grow the SiGe in the SiGe trenches, in sequence. Since growth of Ge or SiGe does not occur on an oxide surface and only occurs on a silicon surface, this approach can provide control of which materials go into which trenches. Typically, threading dislocations (and possibly other defects as well) are concentrated near the interfaces where growth initiates. These defects are referenced as 308 on FIG. 3B.

FIG. 3C shows the result of depositing spin-on-glass 106 on the structure of FIG. 3B. Note that this step effectively planarizes the top surface, even though the structure of FIG. 3B tends to have a significantly non-planar top surface.

FIG. 3D shows the result of depositing electrically conductive poly-silicon 108 on the structure of FIG. 3C. FIG. 3E shows the result of anodically bonding the structure of FIG. 3D to glass substrate 110. FIG. 3F shows the result of removing part of substrate 102 so as to expose Ge 304 and SiGe 306 (the view is flipped about a horizontal axis in going from FIG. 3E to FIG. 3F). This removal can be accomplished by wet etching followed by CMP.

The resulting structure has “islands” of Ge and SiGe laterally surrounded by a silicon matrix, all of which is on a glass substrate. The net effect of the process of FIGS. 3A-F is to transfer target layer(s) having such laterally surrounded islands from the first substrate (where the islands are typically grown), to a glass substrate. The resulting top surface is planar, and defects 308 are naturally removed as part of the substrate removal process. Thus material quality is high. This particular example has Ge and SiGe islands surrounded by silicon. Any other combination of materials could also be employed, as long as all islands can be epitaxially grown in trenches (or other features) in the first substrate. This approach enables planar integration of devices fabricated in different materials, all on a glass substrate. An exemplary application is hyper-spectral imaging, where it can be highly advantageous to have planar integration of devices in different materials (e.g., SiGe bolometers, Ge-GCMD, and silicon read-out integrated circuits).

Another significant feature of the present approach is that a controlled amount of strain can be applied to the target layer(s) once they are on the glass substrate. Thinning the target layers(s) after transferring them to the glass substrate can be used to facilitate and/or control the amount of strain provided (the thinner a layer is, the less force is required to strain it to a given degree, and the less prone it is to crack under strain). In some experiments, the Ge layer was thinned down after the layer transfer to remove the Silicon Germanium (SiGe) layer, which usually forms from the epitaxial growth of Ge on top of silicon. If the Ge layer is not thinned down, high tensile strain will crack the Ge layer. By thinning down the Ge layer, over 1% tensile strain can be applied to the Ge layer.

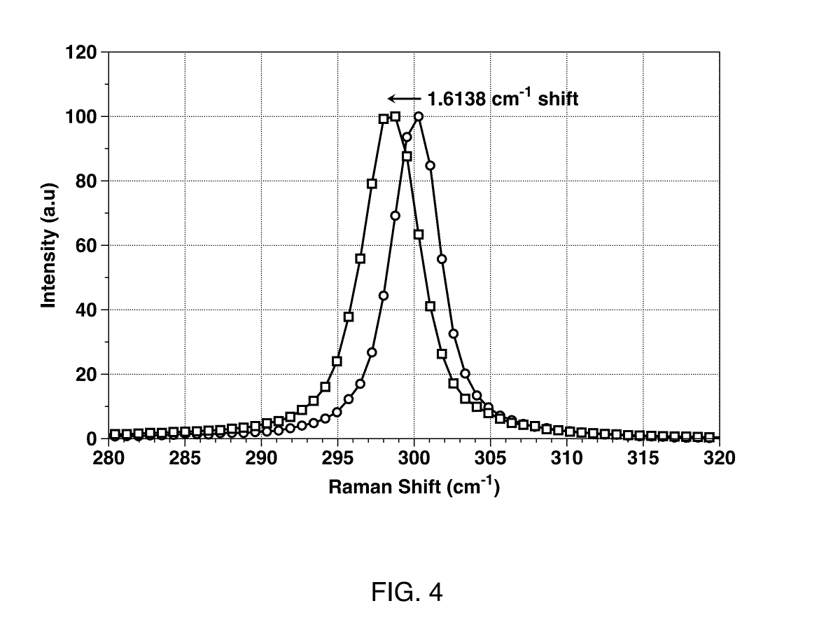

To provide the strain, various techniques can be employed, such as plastic deformation of the glass substrate after transfer of the one or more target layers to the glass substrate. The glass substrate can be stretched/bent (i.e., plastically deformed) at relatively low temperatures (e.g., 500-600° C.). This wasn't possible before the layer transfer since a silicon substrate cannot be plastically deformed at such low temperatures. To deform a silicon substrate requires temperatures over 1200° C., and at such high temperatures, Ge decomposes. A tensile strain of about 0.4% in Ge has been observed by deforming the glass substrate after transfer of a Ge layer to the glass substrate. FIG. 4 shows Raman spectra relating to this result.

Controlled application of strain has various applications. For example, a pseudo-heterostructure can be induced in a single material by suitable application of strain. This is a significant difference compared to conventional approaches where such bandgap engineering is performed by making use of different materials to create the heterostructures. In recent work (Nam et al., “Strain-induced Pseudoheterostructure Nanowires Confining Carriers at Room Temperature with Nanoscale-Tunable Band Profiles”, Nano. Lett. 2013, 13(7) pp. 3118-3123, hereby incorporated by reference in its entirety), a strain induced potential well in a single-material nanowire was used to increase emission efficiency and shift emission wavelength.

Another approach is annealing the spin-on-glass after it is deposited, thereby providing strain to the one or more target layers. Such annealing can be done either before or after the transfer of the target layer(s) to the glass substrate.

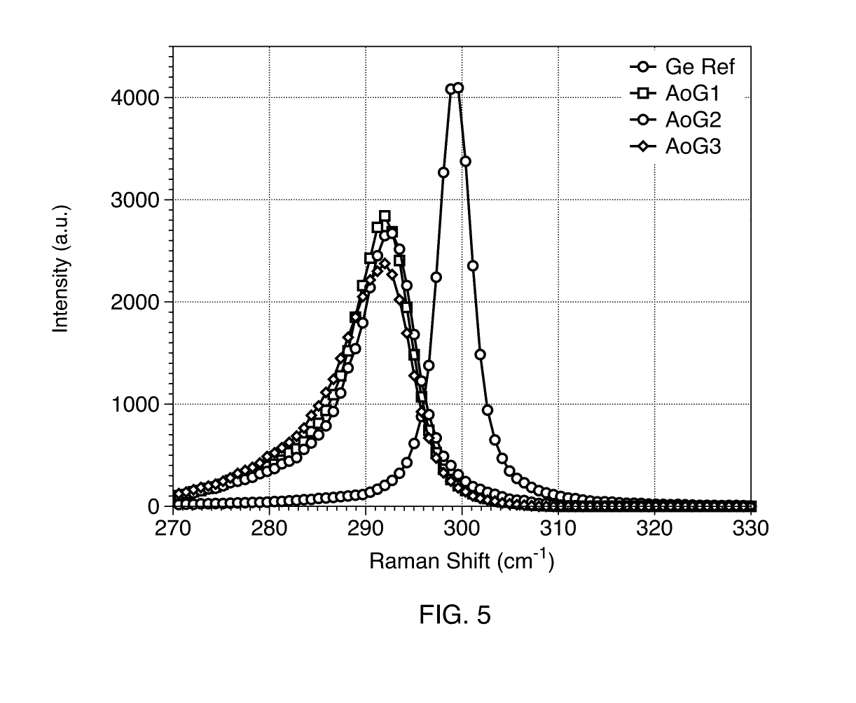

In one experiment, the process of FIGS. 1A-E was followed, except that after deposition of the SOG as shown on FIG. 1B, the structure was annealed at 650° C. for over 6 hours. It is believed that the SOG shrinks during this annealing, thereby eventually providing tensile stress to the germanium layer 104. The remaining steps of the transfer proceed as in FIGS. 1C-E. FIG. 5 shows measured Raman spectra for strained germanium layers that were transferred to a glass substrate in this manner.

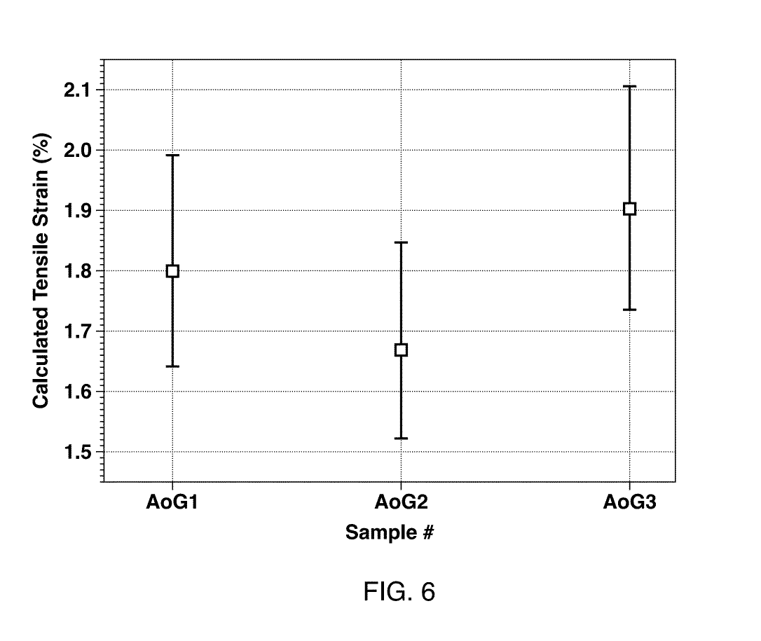

A large and consistent difference in Raman shift is apparent between the Ge control sample, and three AoG (anything on glass) samples where Ge was transferred to glass and strained as described above. FIG. 6 shows strain in the germanium layers calculated from the results of FIG. 5. These results show 1.6% to 2.1% tensile strain in the Ge layer post-transfer. This amount of strain is sufficient to change Ge from an indirect band gap material to a direct band gap material. Since direct band gap materials are much more useful for optical and optoelectronic applications than indirect band gap materials, the availability of highly strained Ge with this approach has significant implications for applications. Highly strained germanium can enable applications such as optical interconnects, transistor-type detectors, LEDs and lasers.

1. A method of bonding one or more target layers to a glass substrate, the method comprising:
providing a first substrate, wherein the one or more target layers are disposed on the first substrate;
depositing spin-on-glass (SOG) onto a top surface of the one or more target layers;
bonding the spin-on-glass to the glass substrate; and
removing the first substrate after the bonding the spin-on-glass to the glass substrate.

2. The method of claim 1, wherein the bonding the spin-on-glass to the glass substrate comprises:
polishing the top surface of the spin-on-glass; and
directly bonding the top surface of the spin-on-glass to the glass substrate using elevated temperature and pressure.

3. The method of claim 2, wherein the polishing the top surface of the spin-on-glass comprises chemical-mechanical polishing.

4. The method of claim 1, wherein the bonding the spin-on-glass to the glass substrate comprises:
depositing an electrically conductive layer on top of the spin-on glass; and
anodically bonding the electrically conductive layer to the glass substrate using an applied electrical voltage combined with elevated temperature and pressure.

5. The method of claim 1, further comprising thinning the one or more target layers after transfer of the one or more target layers to the glass substrate.

6. The method of claim 5, further comprising providing strain to the one or more target layers by plastic deformation of the glass substrate after transfer of the one or more target layers to the glass substrate.

7. The method of claim 1, further comprising annealing the spin-on-glass after it is deposited, thereby providing strain to the one or more target layers.

8. The method of claim 7, wherein the strain provided to the one or more target layers is configured to provide a strain-induced pseudo-heterostructure.

9. The method of claim 7, wherein the strain provided to the one or more target layers is configured to make a material that ordinarily has an indirect band gap have a direct band gap.

10. The method of claim 1, wherein the one or more target layers comprise one or more islands laterally surrounded by a matrix material having a composition different than compositions of the islands.
